(19) United States
(12) Patent Application Publication
(10) Pub. No.: US 2026/0328835 A1
(43) Pub. Date: Oct. 22, 2026

(54) Broadband Attenuators using Thin Film Resistor Technology

(71) Applicant: FormFactor, Inc., Livermore, CA (US)

(72) Inventors: Pratik Bakul Ghate, Beaverton, OR (US); Daniel Bock, Portland, OR (US)

(21) Appl. No.: 19/544,676

(22) Filed: Feb. 19, 2026

Related U.S. Application Data
(60) Provisional application No. 63/760,534, filed on Feb. 19, 2025.

(51) Int. Cl. G01R 31/28; G01R 1/067; G01R 1/073

(52) U.S. Cl. CPC G01R 31/2822; G01R 1/06772; G01R 1/07378

(57) ABSTRACT

Thin film resistor networks are used to provide broadband attenuation in probe heads for testing electrical devices. This approach is highly advantageous compared to the conventional approach of using discrete surface mount technology components to make resistor networks in probe heads. Broadband performance up to at least 100 GHz is demonstrated by simulation and by measurement.

### CROSS REFERENCE TO RELATED APPLICATIONS

This application claims priority from U.S. Provisional Patent Application 63/76,0534 filed Feb. 19, 2025, which is incorporated herein by reference.

### GOVERNMENT SPONSORSHIP

None.

### FIELD OF THE INVENTION

This invention relates to electrical probing of a device or circuit or wafer under test.

### BACKGROUND

Arrays of probes are often used for making temporary electrical contact to devices under test. In some cases, it is necessary to provide attenuation at or near the probe head for device testing. For example, a device under test could need to have a resistive attenuator provided at its output during testing in order to reduce the signal strength. As technology evolves toward higher operation frequencies (generally referred to as “RF”, these have frequency spectrum from 3 KHz-300 GHz), providing such attenuation over a required broad band of frequencies can become challenging.

To achieve RF attenuation, current methodologies, utilize surface mount resistor networks, such as Pi, H, O, L and T configurations. These networks are designed to achieve the desired attenuation over a specified frequency range, while maintaining impedance matching to reduce reflections leading to signal loss. Surface mount resistors are popular due to their compact size, availability in standard values, and ease of integration. However, their performance is detrimentally affected by electromagnetic (EM) parasitics like stray inductance and capacitance in the package, that degrade their capability for broadband or high-frequency applications.

An alternative approach employs active components, such as voltage-controlled attenuators or op-amp-based configurations, to achieve tunable and more precise attenuation control across a wider frequency range. While active designs provide enhanced control and adaptability, they also introduce added complexity, increased power requirements, and potential sources of noise.

Accordingly, it would be an advance in the art to provide improved broadband attenuation in probe heads.

### SUMMARY

### A) General Principles

The approach of this work is a new layout for RF attenuators based around using thin film resistor networks on a single substrate. These thin film resistors have superior performance capabilities when compared to traditional SMT (Surface Mount Technology) components. The design also provides better performance since all the resistors can be fabricated on the same substrate that reduces EM parasitics, whereas more traditional designs utilize discrete resistor components that make it difficult to optimize the full design. This solution also allows for many different resistive attenuator topologies, including Pi, H, O, L and T attenuators, where the entire network is put onto a single substrate that can then be placed on a wafer probe head.

For example, in the case of a thin film based Pi attenuator, the resistor values can be designed using the same methods as a standard SMT Pi attenuator. However, the main difference in values is that each resistor to ground can be designed in such a way that the 1/r1+1/r2=1/r, where r1 and r2 are the two resistances to ground, and r is the Pi attenuator value for connection to ground. By using this methodology, the attenuator design can be balanced, or unbalanced. This allows for flexibility in both design and layout, guided by the constraints of the final application. This methodology can be extended to other types of attenuators as well.

One example use case in wafer test is for testing high-speed data bus chips, where there is a need to have broadband attenuators that operate at the speed of the signals to prevent signal clipping. Traditional SMT designs are not able to operate much above 50 GHz, as well as being physically large for the available space due to using discrete resistors in one physical instantiation of the network. This new attenuator design utilizing thin film fabrication processes is physically compact and provides broadband capabilities. Prior solutions typically were limited due to discrete resistor components being used as SMT components. Using thin film technology, the size of attenuator circuit will be minimized making it suitable to fit in very tight places in a wafer probe head. This provides better ability to optimize the circuit layouts for maximum RF bandwidth.

Significant aspects of this work include the following, individually or in any combination:
Ultra-broadband capability
Use of thin-film resistors
Higher reliability
Better signal integrity
Physically more compact

Practice of the invention does not depend critically on other details of the probe head. In particular, this idea is applicable (but not limited) to probe heads having vertical probes, MEMS probes, probe heads having cantilever probes, as well as membrane based probe heads. With appropriate fabrication methods, these networks could be designed into the probe head space transformer during its fabrication, and not as a separate component. In addition, this can be fabricated as a separate component that could be attached or integrated into the device.

### B) Advantages of This Approach

### 1) A Wide Range of Attenuation is Possible With This Design Approach

As this technology uses resistors designed using thin film technology and does not use surface mount resistors, it provides a broad range of attenuation values, making it highly versatile for different requirements. This capability will cover a broad variety of applications requiring both small and large attenuation without compromising RF performance over broadband.

### 2) Variation of <1 dB for Broadband Frequencies (DC—110 GHz and Above)

This design maintains an exceptionally stable attenuation response with a variation of less than 1 dB over broadband from DC to 110 GHz and above (e.g., the simulation and measurement results of FIGS. 6B, 7B, 8B, 9B, 10B, 11B). This consistency is important for high-frequency applications such as on-wafer measurements where signal integrity is important. This yields the advantage of reduced losses and signal reflections and ensures reliable performance across the entire operating frequency range.

### 3) Balanced and Unbalanced Versions Possible

The design can be implemented in both symmetric and asymmetric configurations, offering design flexibility. This adaptability ensures compatibility with a broader range of systems and applications.

### 4) Wide Range of Resistor Values

The ability to utilize a wide range of resistor values allows the design to meet a range of application-specific attenuation and impedance requirements. This feature enhances its applications, enabling tailored solutions for various circuit designs. It also supports optimization for performance across different frequency ranges and signal types.

### 5) Compact Footprint for Narrow Pitch Applications

The design's compact footprint is particularly advantageous for narrow-pitch applications with severe space constraints. This makes it ideal for modern high-density circuit layouts, especially in integrated systems. Its small size improves performance and enables more efficient use of board space.

### 6) Better Control of EM Parasitics

Enhanced control over electromagnetic parasitics improves the performance of the attenuator in high-frequency applications. This minimizes unwanted effects such as crosstalk and signal degradation, ensuring improved signal integrity. Such control is crucial for maintaining performance in densely packed circuit environments and high-frequency applications.

### 7) Solder Ball/Reflowable on Wafer

The solder ball/reflowable feature simplifies assembly and integration into wafer-level packages. It enhances reliability and manufacturability, reducing the complexity of high-frequency system assembly. This capability ensures a seamless integration process for large-scale production.

### 8) Passive Structures in Some Embodiments

The use of passive structures eliminates the need for external power, reducing complexity and power consumption. Passive designs are inherently more reliable due to the absence of active components, making them suitable for high-reliability applications. They are also cost-effective for large-scale deployment.

### 9) Single and Differential Usage

These thin film attenuators can be used for both single-ended and differential signal (or differential pair) applications since both are common in digital and analog applications. This offers greater design flexibility. This dual capability enhances its applicability across various domains.

### 10) Tolerant to Resistance Variations (Good Fabrication Tolerance)

The design exhibits greater tolerance to resistance variations than traditional SMT based attenuators, thereby ensuring consistent performance despite fabrication inconsistencies. This robustness is important for achieving high yields in manufacturing. It also provides reliability in scenarios with environmental or operational variances.

### 11) Balanced Ground Return for Speeds Upwards of 110 GHz

The design supports a balanced ground return at frequencies exceeding 110 GHz, ensuring stable operation in ultra-high-frequency systems. This feature reduces signal loss and enhances overall performance in advanced RF and microwave applications. It is particularly valuable for maintaining signal integrity in cutting-edge communication systems.

### C) Disadvantages of Conventional SMT Approach

Current designs utilize surface mount resistor networks to set a broadband attenuation in RF circuits.

These have significant disadvantages:

### 1) Limited to Narrowband

Surface mount resistors typically exhibit limited bandwidth performance due to inherent electromagnetic parasitics like capacitance and inductance, that affect their impedance at higher frequencies. These limitations make them unsuitable for applications requiring broadband operation, such as high-frequency RF systems.

### 2) Poor Control of EM Parasitics

Surface mount resistors introduce unwanted electromagnetic parasitics, such as stray inductance and capacitance, that degrade circuit performance, particularly at high frequencies. These parasitics can lead to increased losses, signal distortion, resonance issues, and impedance mismatches, making precise circuit design and tuning challenging.

### 3) Active Circuits and Tuning Required for Broadband Attenuation

To achieve broadband attenuation using surface mount resistors, active circuits or complex tuning networks are often required. These additional components increase design complexity, cost, and manufacturing challenges, leading to yield loss.

### 4) Not a Compact Footprint

While surface mount resistors are relatively small, achieving specific attenuation values often requires a network of multiple resistors, that increases the real estate required to implement the overall footprint. This is a major concern in space-constrained designs, where compact and efficient solutions are needed.

### 5) Harder to Replace Individual Components

Surface mount resistors are soldered directly onto the PCBs, probe cards, space transformers etc., making them challenging to replace without specialized tools and expertise. This complicates repair processes, especially in densely populated boards or intricate designs.

### 6) Attenuation Depends on Available Value of Surface Mount Resistors

The attenuation achievable by the overall attenuation circuit is limited by the discrete values of surface mount resistors available in standard tolerances. This can restrict design flexibility and make it difficult to achieve precise attenuation levels without additional customization or compromise.

### BRIEF DESCRIPTION OF THE DRAWINGS

FIGS. 1A-C show three exemplary embodiments of the invention.

FIG. 2 shows an exemplary fabrication sequence for thin-film resistor technology.

FIGS. 3A-F show several exemplary circuit diagrams for resistive attenuator networks.

FIGS. 4A-F show exemplary thin-film resistor layouts that correspond to the circuit diagrams of FIGS. 3A-F.

FIGS. 5A-D show several exemplary attenuator networks including active devices.

FIG. 6A shows a thin film resistor layout for a single-ended H-attenuator designed to have −10 dB insertion loss.

FIG. 6B shows simulated and measured results for the thin film resistor layout of FIG. 6A.

FIG. 7A shows a thin film resistor layout for a single-ended H-attenuator designed to have −15 dB insertion loss.

FIG. 7B shows simulated and measured results for the thin film resistor layout of FIG. 7A.

FIG. 8A shows a thin film resistor layout for a differential pair H-attenuator designed to have −10 dB insertion loss.

FIG. 8B shows simulated and measured results for the thin film resistor layout of FIG. 8A.

FIG. 9A shows a thin film resistor layout for a differential pair H-attenuator designed to have −12 dB insertion loss.

FIG. 9B shows simulated and measured results for the thin film resistor layout of FIG. 9A.

FIG. 10A shows a thin film resistor layout for a differential pair H-attenuator designed to have −15 dB insertion loss.

FIG. 10B shows simulated and measured results for the thin film resistor layout of FIG. 10A.

FIG. 11A shows a thin film resistor layout for a differential pair H-attenuator designed to have −20 dB insertion loss.

FIG. 11B shows simulated and measured results for the thin film resistor layout of FIG. 11A.

### DETAILED DESCRIPTION

### A) Examples

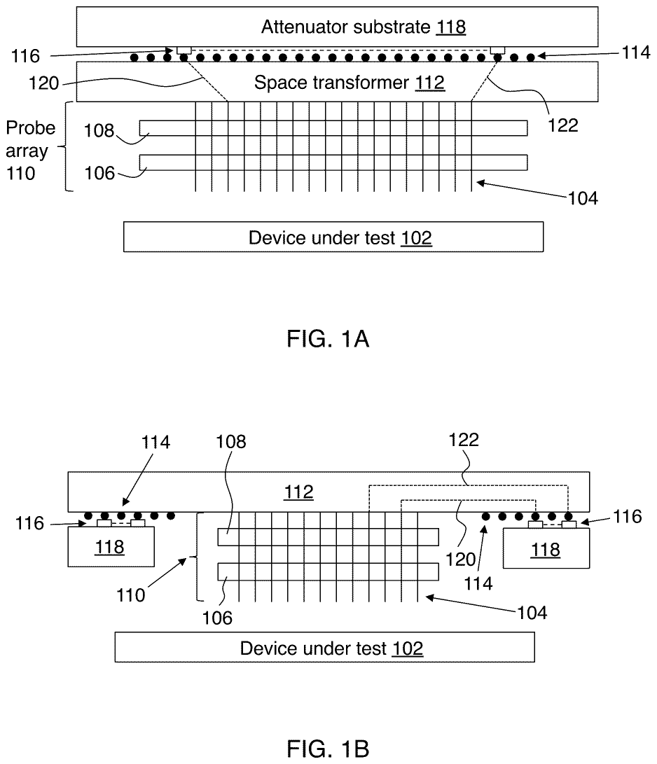

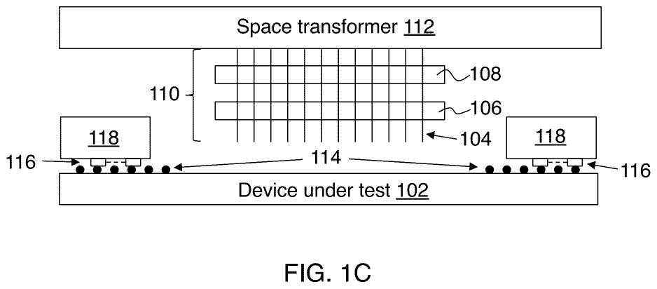

FIGS. 1A-C shows different instantiations of the system architecture on which thin film attenuators will be used. FIG. 1A shows a configuration with the thin film attenuators making electrical contact to the top side of the space transformer (i.e., the opposite side from the probe array). FIG. 1B shows a configuration with the thin film attenuators making electrical contact to the bottom side of the space transformer (i.e., the same side as the probe array). FIG. 1C shows a configuration with the thin film attenuators making electrical contact to the device under test. Any combination of these three possibilities can also be employed.

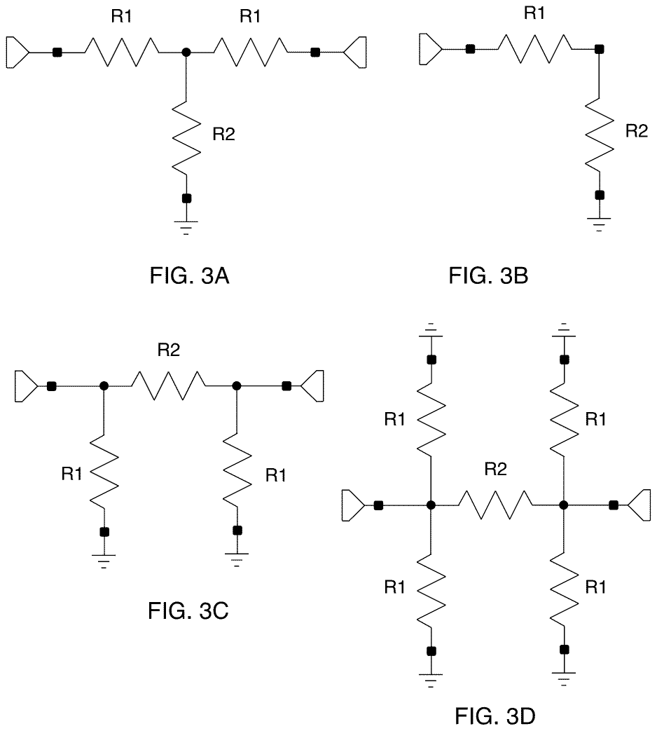

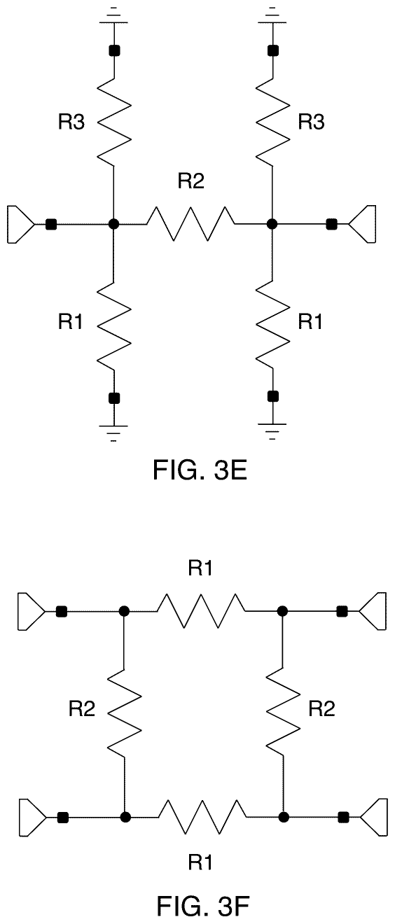

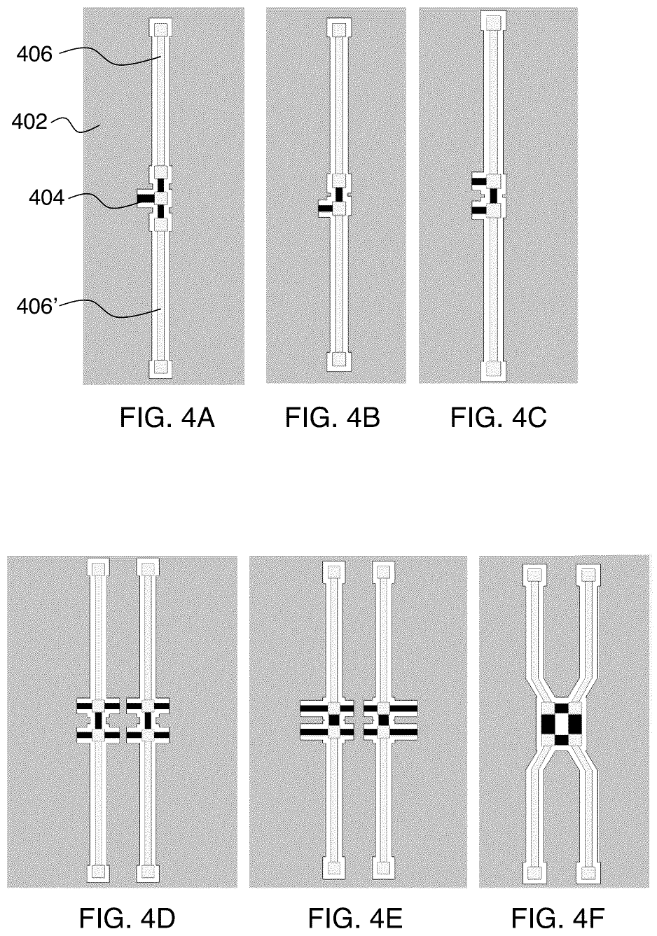

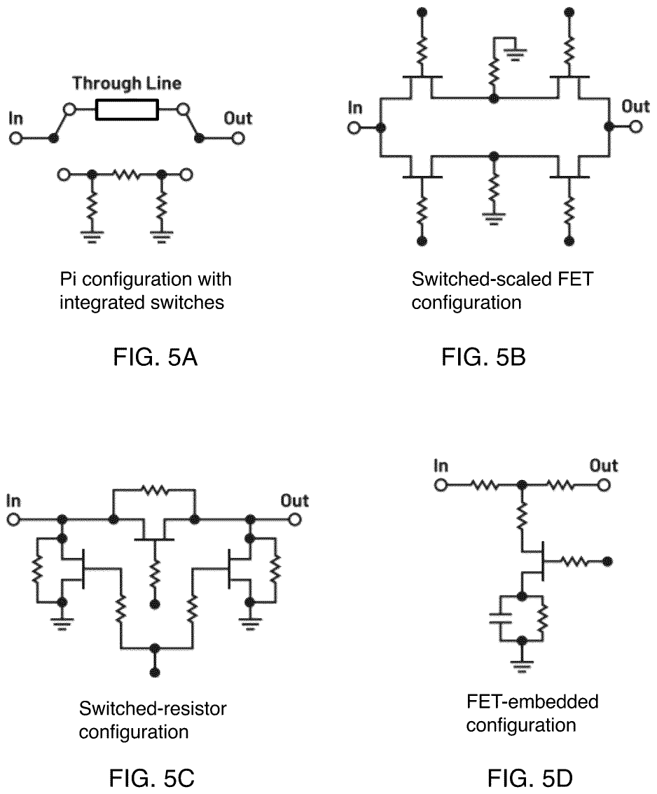

In the example of FIG. 1A, a device under test 102 can be probed with a probe head that includes a probe array 110 and a space transformer 112. Probe array 110 can be any kind of probe head, but as an illustrative example we schematically show probe head 110 as including vertical probes 104 that are mechanically guided by lower guide plate 106 and upper guide plate 108. In this example, the top surface of space transformer 112 includes bump contacts 114 (e.g., solder balls or the like) that make contacts to gold pads on thin film resistor attenuator network(s) 116 disposed on attenuator substrate 118. Here 116 is a schematic side view of the thin film resistor attenuator network(s), and FIGS. 3A-5D below provide various examples of schematics (FIGS. 3A-F, FIGS. 5A-D) and layouts (FIGS. 4A-F) the thin film resistor attenuator network(s) can include. As an example of the capability provided by thin film resistor attenuator network(s) 116, current paths 120 and 122 through space transformer are shown. Here the corresponding probes are electrically connected at their bases via a current path that includes current path 120, current path 122, and thin film resistor attenuator network(s) 116.

The example of FIG. 1B differs from the example of FIG. 1A in the location of the thin film resistor attenuator network(s) 116 and a corresponding change in the location of attenuator substrate 118. Here the thin film attenuators 116 make electrical contact to the bottom side of the space transformer (i.e., the same side as the probe array).

The example of FIG. 1C differs from the example of FIG. 1A in the location of the thin film resistor attenuator network(s) 116 and a corresponding change in the location of attenuator substrate 118. Here the thin film attenuator network(s) 116 make electrical contact to the device under test. Some devices under test have bump contacts suitable for making electrical contact to the thin film resistor attenuator network(s) 116, and this configuration accounts for that possibility.

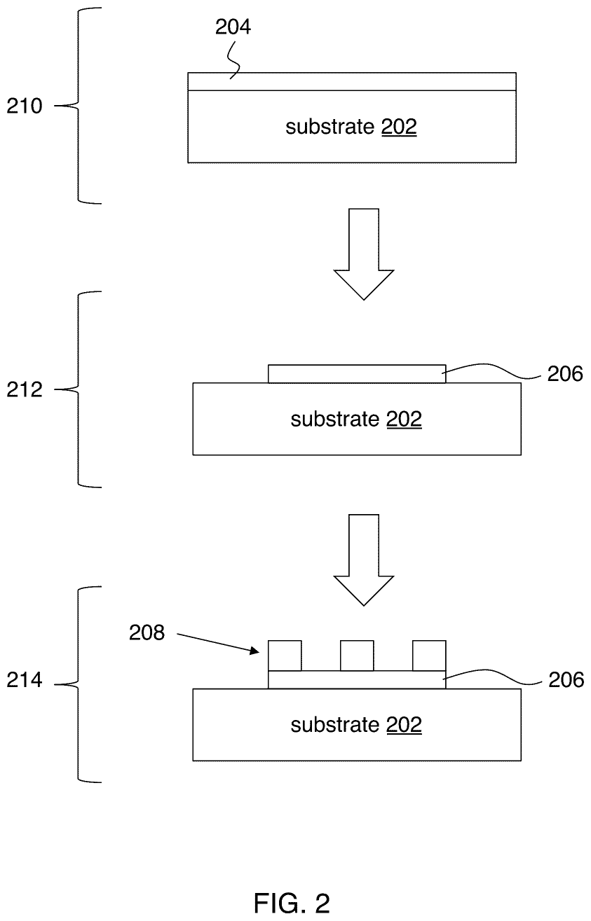

FIG. 2 shows an exemplary fabrication sequence for thin-film resistor technology. This technology is known in the art, so the following is a brief overview of fabrication. 210 on FIG. 2 shows the result of a first fabrication step where a resistive material 204 is deposited on a substrate 202. Practice of the invention does not depend critically on the composition of these materials, or on the deposition method. For example, the deposition method can be sputtering, the substrate can be alumina and the resistive material can be carbon, tantalum oxide, molybdenum disulfide, tantalum nitride or nichrome. 212 on FIG. 2 shows the result of patterning resistive material 204 (e.g., via lithography followed by etching) to provide resistor structures 206. 214 on FIG. 2 shows the result of depositing a conductive material (e.g., gold) and then patterning the conductive material to provide contacts 208, conductive traces and ground features. Again, this patterning can be done by lithography followed by etching. After this step, an optional trimming step can be performed to adjust fabricated resistance values to better match the intended design values.

FIGS. 3A-F show exemplary circuit schematics for several attenuator configurations, and FIGS. 4A-F show top views of corresponding realizations of these attenuator configurations as thin film resistor networks. On FIGS. 4A, 402 is a ground, 406 and 406′ are metal contacts and the black rectangles (e.g. 404) are the thin-film resistors. FIGS. 4B-F have this same legend, where the black features are the thin-film resistors, a ground laterally surrounds the network, and metal traces separated from the ground make contact to the resistive network. The correspondence between the circuit schematics of FIGS. 3A-F and the thin-film resistor layouts of FIGS. 4A-F is apparent, with the minor complication that FIGS. 4D-E show differential pair balanced-H (FIG. 4D) and differential pair unbalanced-H (FIG. 4E) networks, while the corresponding schematics of FIGS. 3D-E show single-ended configurations of these networks.

In some preferred embodiments H-attenuators are used because they provide stable broadband performance, they are suitable for both single-ended and differential configurations, they tend to have low EM parasitics, they tend to be tolerant to process variations and tend to provide a batter thermal distribution than other configurations. One example of the advantages provided by thin film resistor networks is the ability to implement the balanced-H configuration of FIGS. 3D and 4D.

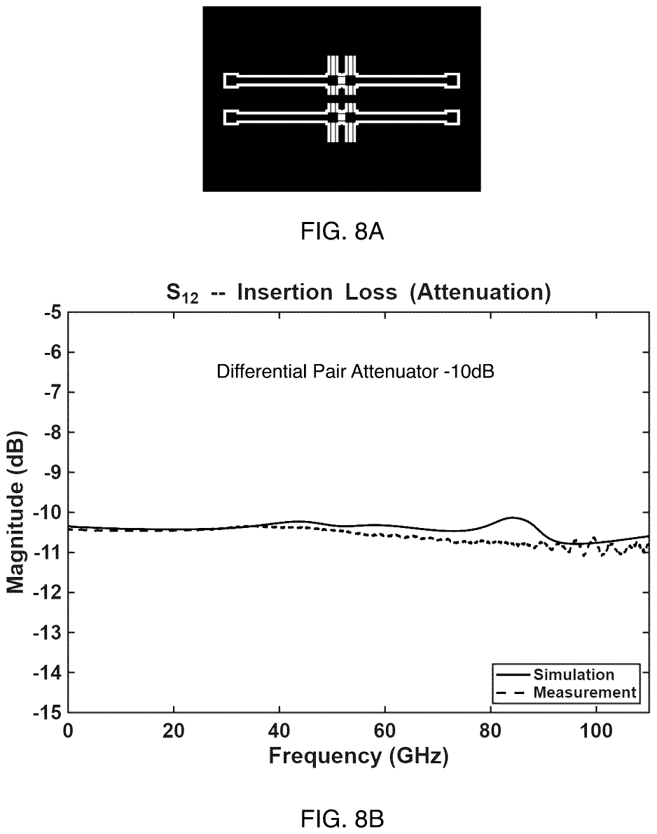

FIGS. 3D and 4D illustrate a modification of the H type attenuator fabricated using thin film processes that have balanced return currents, whereas different resistor values, leads to an unbalanced H-attenuator as on FIG. 3E and FIG. 4E. Conventional design layouts with SMT components results in limited bandwidth due to poor control on EM parasitics and assembly variations. In contrast, FIGS. 3D, 3E, 4D and 4E show H-attenuator layout, resulting in wider bandwidth capability when compared to existing designs. Simulations and measurements indicate that this design should operate at frequencies ≥110 GHz with attenuation that is tunable based on the relative values of the resistors (see FIGS. 8B, 9B, 10B, 11B). For example, current designs are to select attenuation from less than −10 dB to more than −20 dB, but other values are selectable based on the needs of the application.

In addition, our modification of the H-attenuator will improve broadband frequency performance by better controlling the return currents in the design, which is important for frequencies above 60 GHz. The next generation of devices will be operated at frequencies above 110 GHz, requiring a new design approach.

The preceding examples all relate to purely passive thin-film resistor networks. The general thin-film resistor fabrication approach of FIG. 2 can be extended to thin-film resistor networks including relatively simple active device configurations according to known techniques. Thus thin-film resistor attenuator networks as considered herein can include active devices in any known active device attenuator configuration. FIGS. 5A-D show some exemplary circuit diagrams of known active device attenuator configurations, taken from the literature.

### B) Results

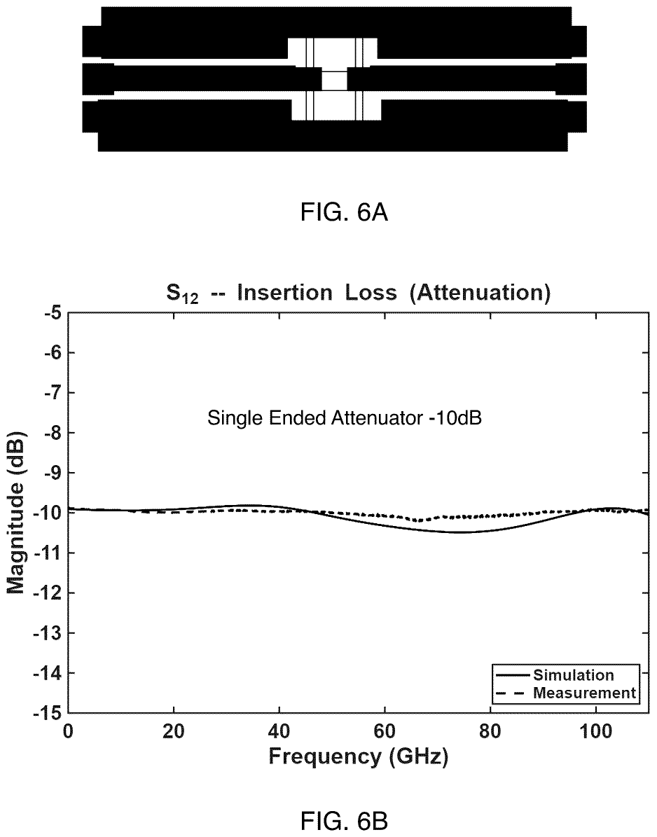

FIG. 6A shows a thin film resistor layout for a single-ended H-attenuator designed to have −10 dB insertion loss. Here and in the following layout examples, the solid black features are metal traces and grounds, and the outline rectangles are the thin-film resistors.

FIG. 6B shows simulated and measured results for the thin film resistor layout of FIG. 6A.

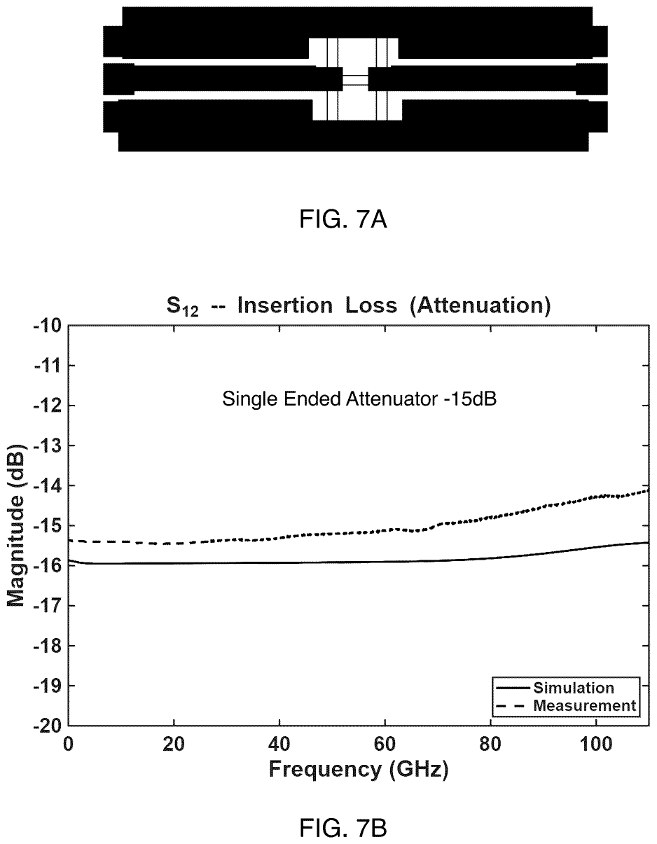

FIG. 7A shows a thin film resistor layout for a single-ended H-attenuator designed to have −15 dB insertion loss.

FIG. 7B shows simulated and measured results for the thin film resistor layout of FIG. 7A.

FIG. 8A shows a thin film resistor layout for a differential pair H-attenuator designed to have −10 dB insertion loss.

FIG. 8B shows simulated and measured results for the thin film resistor layout of FIG. 8A.

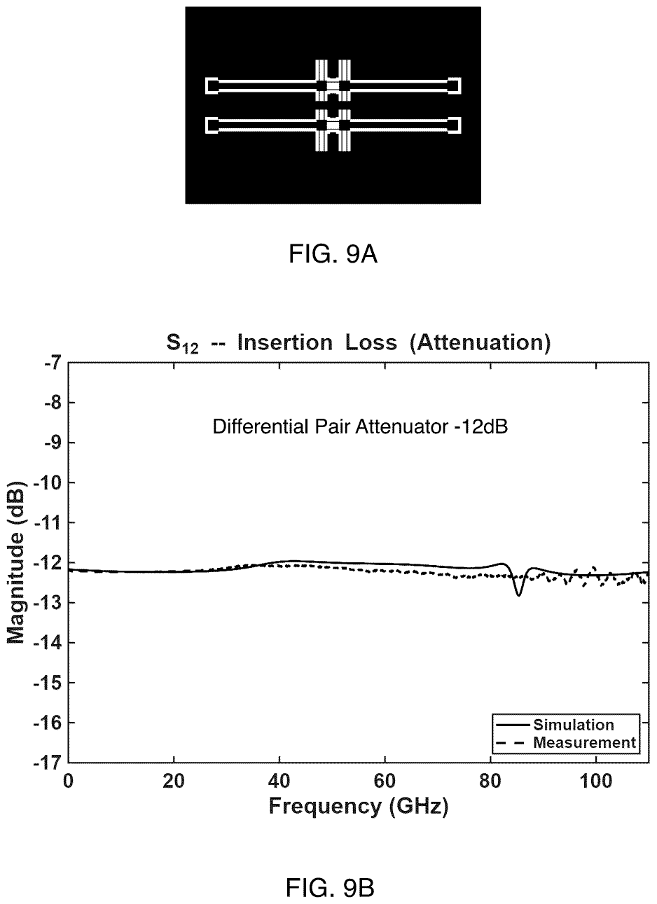

FIG. 9A shows a thin film resistor layout for a differential pair H-attenuator designed to have −12 dB insertion loss.

FIG. 9B shows simulated and measured results for the thin film resistor layout of FIG. 9A.

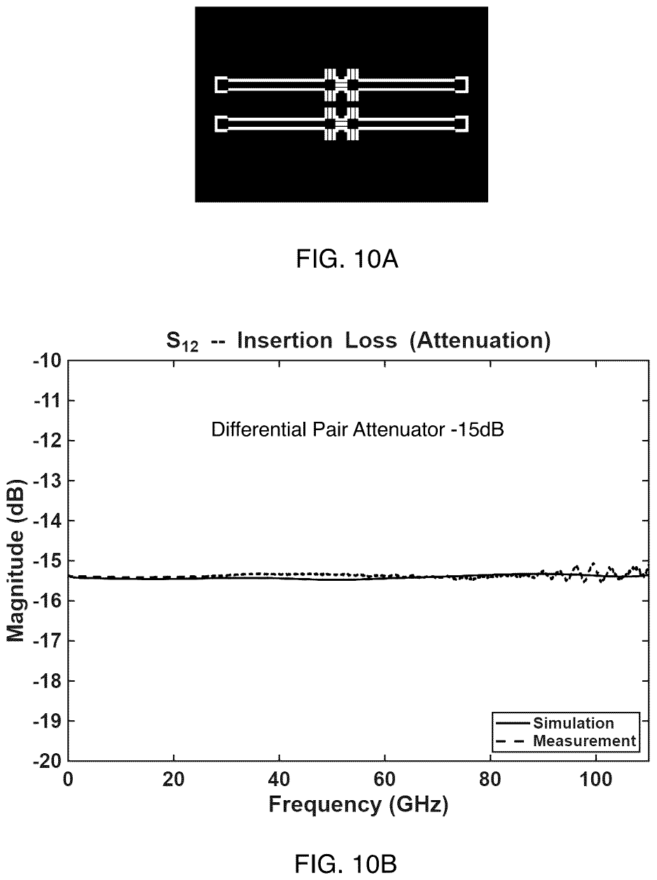

FIG. 10A shows a thin film resistor layout for a differential pair H-attenuator designed to have −15 dB insertion loss.

FIG. 10B shows simulated and measured results for the thin film resistor layout of FIG. 10A.

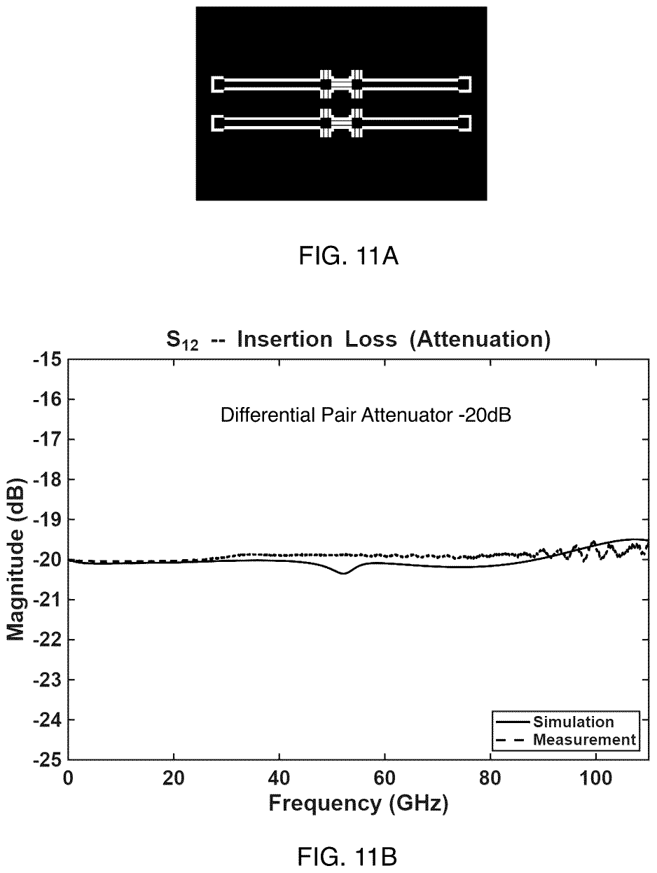

FIG. 11A shows a thin film resistor layout for a differential pair H-attenuator designed to have −20 dB insertion loss.

FIG. 11B shows simulated and measured results for the thin film resistor layout of FIG. 11A.

1. A probe head comprising:
an array of probes, wherein each probe includes a tip configured to make electrical contact to a device under test and a base opposite the tip;
a space transformer, wherein the bases of the probes are affixed to the space transformer and wherein the bases of the probes make electrical connections to the space transformer;
at least one attenuator structure configured as a thin-film resistor network including one or more resistive attenuation networks;

2. The probe head of claim 1, wherein the attenuator structure is disposed to make electrical contact to contacts disposed on a side of the space transformer facing away from the device under test.

3. The probe head of claim 2, wherein the space transformer includes at least one electrical connection through the space transformer configured to electrically connect at least one of the probes to the attenuator structure.

4. The probe head of claim 1, wherein the attenuator structure is disposed to make electrical contact to contacts disposed on a side of the space transformer facing the device under test.

5. The probe head of claim 4, wherein the probe head includes one or more guide plates configured to provide mechanical guidance to the probe array, and wherein the attenuator structure is not disposed on any of the one or more guide plates.

6. The probe head of claim 1, wherein the attenuator structure is disposed to make electrical contact to contacts disposed on the device under test.

7. The probe head of claim 6, wherein the probe head includes one or more guide plates configured to provide mechanical guidance to the probe array, and wherein the attenuator structure is not disposed on any of the one or more guide plates.

8. The probe head of claim 1, wherein the one or more resistive attenuation networks are passive.

9. The probe head of claim 1, wherein the one or more resistive attenuation networks include one or more active devices.

10. The probe head of claim 1, wherein the one or more resistive attenuation networks include at least one single-ended attenuation network.

11. The probe head of claim 1, wherein the one or more resistive attenuation networks include at least one differential pair attenuation network.

12. The probe head of claim 1, wherein the one or more resistive attenuation networks include one or more attenuator configurations selected from the group consisting of: T-attenuators, L-attenuators, Pi-attenuators, H-attenuators, balanced H-attenuators, unbalanced H-attenuators, O-attenuators, attenuators including integrated switches, attenuators including switched-scaled transistors, attenuators including switched resistors, and attenuators including embedded transistors.
